(19) United States
(12) Patent Application Publication
(10) Pub. No.: US 2026/0347175 A1
(43) Pub. Date: Nov. 5, 2026

(54) Method for Fabricating Membrane-Film Microbolometer Thermal Sensor Hybridized with Readout Integrated Circuit

(71) Applicant: National Chung Shan Institute of Science and Technology, Taoyuan (TW)

(72) Inventors: Shiang-Feng Tang, Taoyuan (TW); MU-MIN CHEN, Taoyuan (TW); Hsin-Chang Chen, Taoyuan (TW); Hong-Yuan Zeng, Taoyuan (TW); Bing-Fang Tsai, Taoyuan (TW)

(21) Appl. No.: 19/199,361

(22) Filed: May 5, 2025

(51) Int. Cl. B81C 1/00; B81B 7/00

(52) U.S. Cl. CPC B81C 1/00238; B81B 7/0077; B81B 2201/0207; B81B 2207/012; B81B 2207/07; B81C 2201/0104; B81C 2201/0105; B81C 2201/0132; B81C 2201/0156; B81C 2201/0176; B81C 2201/0181; B81C 2203/032

(57) ABSTRACT

The present invention provides a fabrication method for a membrane-film microbolometer thermal sensor hybridized with a readout integrated circuit. In addition to a conventional MEMS thin-film process, this method integrates wafer thinning, backside silicon (or glass substrate) via formation, and metal sputtering or electroplating filling. Furthermore, a hybrid wafer-level metal bonding technique is employed, which differs entirely from the conventional post-process architecture of directly integrating a MEMS microbolometer thermal sensor onto a ROIC wafer. This method effectively reduces image signal noise interference and signal latency issues caused by the signal routing in a COF (Chip on Film) packaging process.

### BACKGROUND

### 1. Field of the Invention

The present invention relates to a fabrication method for a microbolometer thermal sensor, and more particularly to a fabrication method for a microbolometer thermal sensor hybridized with a readout integrated circuit (ROIC).

### 2. Description of the Related Art

A conventional membrane-film microbolometer thermal sensor (Membrane-Film Microbolometer Thermal Sensor) mainly comprises a stacked membrane film developed using micro-electromechanical system (MEMS) technology, a plurality of posts supporting the membrane, and connecting metal layers located at the bottom and surrounding the posts for conducting the electrical signals of the sensing element to connection metal areas on a readout integrated circuit (ROIC) underneath. Finally, the sensed current or voltage signals are conducted smoothly through the connecting metal structure inside the posts to enable subsequent signal processing within the ROIC.

Conventionally, the stacked membrane film developed with MEMS technology is fabricated directly on the ROIC wafer to integrate the membrane-film microbolometer thermal sensor through a post process. The final structure forms a thermal imaging sensor array wafer integrated with the ROIC circuit.

Generally, when fabricating the membrane-film microbolometer thermal sensor using MEMS technology, the MEMS post process is performed directly on the ROIC wafer after the ROIC wafer is completed. This process structure has the following main drawbacks:
1. During the MEMS post process, it is necessary to consider the maximum process temperature tolerance of the ROIC wafer and the high and low temperature process cycles it can withstand. The temperature parameters of the membrane support layer in the MEMS membrane floating plate process are limited by the maximum temperature tolerance of the underlying ROIC circuit. To obtain a high-quality and high-yield membrane microbolometer sensor, it is necessary to produce a low-stress floating plate support layer. Generally, increasing the deposition temperature in the plasma-enhanced chemical vapor deposition (PECVD) process helps achieve stress relief on the floating plate. However, due to the aforementioned constraints, complex stress compensation and balancing design between the silicon nitride layers of the floating plate are required. This also narrows the process temperature window (in addition to the deposition temperatures of the silicon nitride layer of the floating plate and the intermediate infrared sensing layer, the ratio of synthetic gases in the chamber and the flow rate of reactive gases must also be precisely adjusted), greatly increasing the complexity of the process.
2. The prior art requires obtaining the ROIC wafer before performing the MEMS post process to fabricate the microbolometer thermal sensor. Since this is a serial process architecture, the process cannot be carried out independently and simultaneously. Once the wafer process parameters are optimized and the learning curve is mature, upon transitioning to mass production after engineering verification, the back-end MEMS process capacity is easily affected by the front-end ROIC wafer process capacity. Furthermore, the flatness of the ROIC wafer surface during the front-end process will increase the sensitivity of the yield of the floating plate support posts and the stress distribution of the support layer during the back-end MEMS process, leading to greater variability and complexity in the entire process. The above factors are the main reasons limiting capacity and yield improvement.
3. Performing MEMS processes on non-silicon-based substrates (e.g., glass substrates) for fabricating the floating plates of microbolometer thermal sensors can solve the drawbacks mentioned in items 1 and 2. However, after the ROIC wafer is manufactured, it needs to be diced into dies. For example, in TFT LCD manufacturing, COF (Chip on Film) packaging is used to solder the sensor's multiplexed transistor switching terminals to the column input terminals of the ROIC via flexible circuits. Although this packaging structure increases the distance between the sensor and the ROIC, greatly preventing thermal overflow from the ROIC to the microbolometer sensor and reducing thermal noise interference in the sensor, it sacrifices chip area and introduces electrical coupling noise between analog signal lines (between the microbolometer thermal sensor and the ROIC connection COF flexible circuits). The long flexible circuits also reduce the frame rate of the imaging chip.

In summary, the current fabrication methods for microbolometer thermal sensors hybridized with ROIC still have drawbacks. Therefore, after extensive research and development, the applicant of this application has developed a fabrication method for a microbolometer thermal sensor hybridized with a ROIC, which not only improves the overall yield of conventional MEMS post processes but also enables hybrid bonding between MEMS sensor components on heterogeneous wafers and ROIC silicon-based standard CMOS logic process wafers. This reduces image signal noise interference and signal latency issues caused by COF (Chip on Film) lead processes in signal logic routing conductors.

### SUMMARY

In view of the above-mentioned three major drawbacks of the known techniques, the primary objective of the present invention is to provide a fabrication method for a microbolometer thermal sensor hybridized with a readout integrated circuit (ROIC). In addition to the conventional MEMS membrane process, this method integrates wafer thinning processes and backside silicon (or glass substrate) through-hole formation with metal sputtering or electroplating filling, followed by hybrid wafer-level metal bonding technology. This approach is completely different from the conventional post-process structure in which a MEMS membrane microbolometer thermal sensor is directly fabricated on the ROIC wafer. In this concept, we propose a feasible process flow that not only improves the overall yield of conventional MEMS post processes but also enables hybrid bonding between MEMS sensor elements on heterogeneous wafers and silicon-based ROIC standard CMOS logic process wafers. This is expected to reduce image signal noise interference and signal latency issues caused by signal routing conductors due to the COF (Chip on Film) lead process.

To achieve the above objective, the fabrication method for a microbolometer thermal sensor hybridized with a readout integrated circuit according to the present invention comprises the following steps: (A) forming a sacrificial layer coating on a semiconductor silicon substrate or glass substrate, and completing a microbolometer thermal sensor by a MEMS process using plasma-enhanced chemical vapor deposition (PECVD) and sputtering processes; (B) flipping the entire wafer of the microbolometer thermal sensor and forming a bonding layer, wherein the bonding layer is bonded and cured with a support substrate; (C) thinning the semiconductor silicon substrate or glass substrate by a thinning process, and then performing a hole patterning with yellow light lithography process at coordinate points that match two metal contact points of metal pads of the microbolometer thermal sensor; (D) after the hole patterning with yellow light lithography process, using a reactive ion etching (RIE) machine to etch through the hole, and then filling the hole with metal by sputtering or electroplating; (E) performing chemical mechanical polishing (CMP) to remove metal outside the hole and further thin the semiconductor silicon substrate or glass substrate; (F) hybrid bonding the wafer to a readout integrated circuit wafer via a flip-chip metal bonding process; (G) removing the bonding layer and debonding the support substrate by a de-waxing process or by using a photo-thermal conversion release agent; and (H) removing the sacrificial layer by oxygen plasma to complete the microbolometer thermal sensor wafer hybridized with a readout integrated circuit.

Preferably, the thinning process of step (C) may comprise a physical rough grinding and fine grinding process, followed by a chemical-mechanical polishing process to reduce surface roughness when the thickness of the semiconductor silicon substrate or glass substrate is less than or equal to 30 μm.

Preferably, the thickness of the metal sputtering or electroplating in step (D) may exceed the hole depth by 10 μm.

Preferably, after grinding in step (E), the thickness of the semiconductor silicon substrate or glass substrate may be 20 μm.

Additionally, to achieve the above objective, the fabrication method for a microbolometer thermal sensor hybridized with a readout integrated circuit according to the present invention comprises the following steps: (A) on a semiconductor silicon substrate or glass substrate, performing a hole patterning with yellow light lithography process at coordinate points matching the positions of two metal contact points of metal pads of a microbolometer thermal sensor in each pixel, and etching through the hole using a reactive ion etching (RIE) machine; (B) filling the hole with metal by sputtering or electroplating; (C) performing chemical mechanical polishing (CMP) to remove metal outside the hole and thin the semiconductor silicon substrate or glass substrate so that the hole depth is reduced to 30 μm; (D) forming a sacrificial layer coating and completing a microbolometer thermal sensor by a MEMS process using PECVD and sputtering processes; (E) forming a bonding layer on the microbolometer thermal sensor, wherein the bonding layer is bonded and cured with a support substrate; (F) thinning the semiconductor silicon substrate or glass substrate, and exposing the metal in the hole after polishing; (G) hybrid bonding the wafer to a readout integrated circuit wafer via a flip-chip metal bonding process; (H) removing the bonding layer and debonding the support substrate by a de-waxing process or by using a photo-thermal conversion release agent; and (I) removing the sacrificial layer by oxygen plasma to complete the microbolometer thermal sensor wafer hybridized with a readout integrated circuit.

Preferably, the hole depth after etching in step (A) may be greater than 50 μm.

Preferably, the metal in step (B) may be copper.

Preferably, after the thinning process of step (F), the thickness of the semiconductor silicon substrate or glass substrate may be less than 50 μm.

The above summary, along with the following detailed description and accompanying drawings, further illustrate the means, techniques, and effects employed by the present invention to achieve the intended objectives. Other objectives and advantages of the present invention will be described and illustrated in the subsequent sections and figures.

### BRIEF DESCRIPTION OF THE DRAWINGS

FIGS. 1 to 9 are process schematic diagrams of a first embodiment of the fabrication method for a microbolometer thermal sensor hybridized with a readout integrated circuit according to the present invention.

FIGS. 10 to 18 are process schematic diagrams of a second embodiment of the fabrication method for a microbolometer thermal sensor hybridized with a readout integrated circuit according to the present invention.

### DESCRIPTION OF THE PREFERRED EMBODIMENTS

The following describes embodiments of the present invention through specific examples. Those skilled in the art can easily understand the advantages and effects of the present invention based on the content disclosed in this specification.

In view of the three major drawbacks described in the prior art, the present invention provides a fabrication method for a microbolometer thermal sensor hybridized with a readout integrated circuit. This fabrication method combines separate and independent fabrication processes of heterogeneous chips (the microbolometer thermal sensor and the readout integrated circuit). The following methods address the above drawbacks:
1. By using plasma-enhanced chemical vapor deposition (PECVD) to deposit high-temperature layers (e.g., silicon nitride) on the membrane interlayer of the microbolometer thermal sensor, the residual stress between layers can be reduced, providing a wider process temperature window. On one hand, the increased deposition temperature of the silicon nitride facilitates achieving a low-stress membrane interlayer, improving the support and uniformity of the membrane. On the other hand, the broad deposition temperature range that meets stress specifications allows for more flexible combinations of synthesis gas ratios and reaction gas flow parameters inside the deposition chamber, significantly reducing process complexity and improving the yield of the microbolometer thermal sensor.
2. Since the floating structure of the microbolometer thermal sensor can be fabricated using MEMS processes on a flat silicon or glass substrate, the yield of the floating structure can be significantly improved. Furthermore, the readout integrated circuit chips can be individually and synchronously tested, enhancing overall production capacity and yield.
3. If a non-silicon substrate (e.g., glass substrate) is used, after completing the MEMS process for the floating sensor structure, the front-side sensing element is protected and bonded to a support wafer. Then, thinning, via formation, and metal filling or sputtering are performed on the backside, followed by direct heterogeneous bonding to a silicon-based readout integrated circuit wafer. Afterward, the support wafer is de-bonded. At this point, the thinned sensor wafer is hybridized with the silicon-based readout integrated circuit wafer through metallic contact. Finally, an oxygen plasma process is performed to remove the polyimide (PI) sacrificial layer under the membrane, forming a microbolometer thermal sensor supported by support posts. The detailed implementation of these methods will be described in the following two distinct process flows to achieve the final hybrid bonding of the microbolometer sensor and the readout integrated circuit chip.

The following describes the primary structure of the fabrication process for the hybrid bonding of the microbolometer thermal sensor and the readout integrated circuit chip. In the present invention, this hybrid fabrication method integrates backside thinning, via formation, metal deposition, and hybrid metal bonding with the readout integrated circuit wafer, resulting in a microbolometer thermal sensor with readout integrated circuit signal readout capability. However, the application of the present invention is not limited to this. Any semiconductor process that requires metal signal connections through backside holes between homogeneous or heterogeneous components and circuits can be applied.

Please refer to FIGS. 1 to 9, which are process schematic diagrams of a first embodiment of the fabrication method for a microbolometer thermal sensor hybridized with a readout integrated circuit according to the present invention.

On a silicon or glass substrate 1, a MEMS process is used to sequentially deposit a metal IR reflective layer (thickness 300 nm to 700 nm), coat a PI sacrificial layer 2 (thickness 3 μm to 4 μm), perform high-temperature curing (thickness reduced to 2 μm to 3 μm), and perform photolithography to define the membrane area of the microbolometer thermal sensor (designed according to pixel size). Then, PECVD and sputtering processes are used to sequentially deposit a membrane support layer (dielectric material such as SiNx or SiOx, but not limited thereto), an IR absorbing layer (metal oxide material such as VOx or TiOx, but not limited thereto), a device metal connection layer (primarily vanadium metal or other metals that form ohmic contact with the IR absorbing layer), and a top coating layer (same material as the membrane support layer). The total stress of the laminated materials is between −100 MPa and 100 MPa. Upon completion, the structure of the microbolometer thermal sensor (before removing the PI sacrificial layer 2) is shown in FIG. 1, which differs from traditional methods where the MEMS process is performed directly on a completed ROIC wafer.

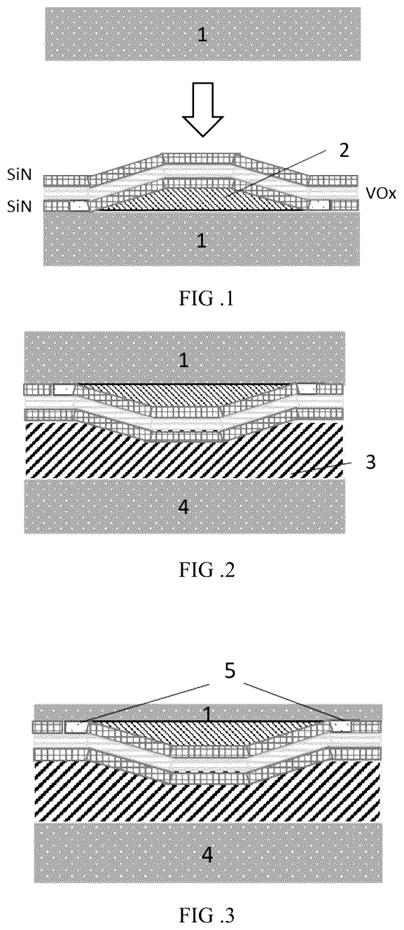

The wafer with the microbolometer thermal sensor completed on the silicon or glass substrate 1 is flipped, and a resin wax film, adhesion enhancer, or liquid UV-curable adhesive is applied as an adhesive layer 3. The adhesive layer 3 is bonded to a support substrate 4 (which can be a silicon or glass substrate) by heating (≤200 °C, preheated to 100 °C for 5-10 minutes to remove air bubbles and ensure bond strength and flatness) or by UV curing (without heating), as shown in FIG. 2.

The silicon or glass substrate 1 undergoes a thinning and grinding process, which comprises coarse and fine grinding steps. When the thickness is reduced to ≤30 μm, chemical-mechanical polishing (CMP) is used to reduce surface roughness. Then, a hard mask layer (SiOx in this embodiment) is deposited by PECVD, and double-sided photolithography is used to align and define the backside hole locations, which must match the coordinates of the vanadium metal contact points 5 of the microbolometer thermal sensor, as shown in FIG. 3.

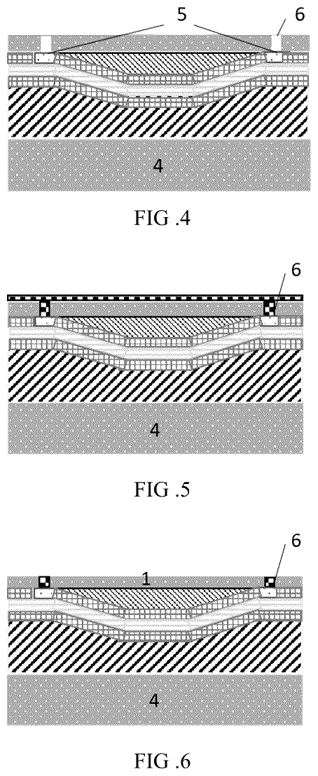

After photolithography, a reactive ion etching (RIE) process is used to etch a hole 6, as shown in FIG. 4. The hole 6 are then filled with metal by sputtering or electroplating, with the metal thickness exceeding the hole depth by 10 μm, as shown in FIG. 5.

A CMP process is performed to remove the metal outside the hole 6 and further reduce the thickness of the silicon or glass substrate 1 by 10 μm, leaving a remaining thickness of 20 μm, as shown in FIG. 6.

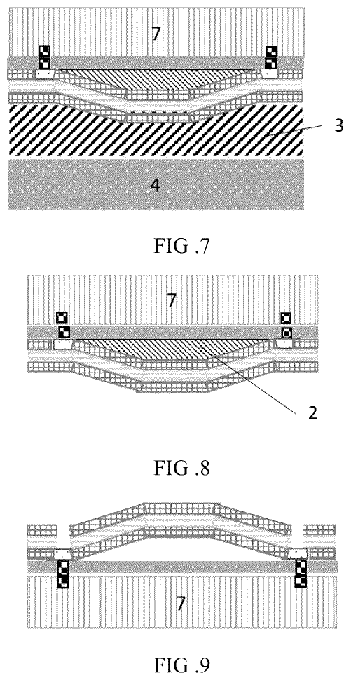

A flip-chip hybrid metal bonding process is performed to bond the wafer to a readout integrated circuit wafer 7, achieving precise fusion bonding under heating and pressure. At this stage, there is almost no gap between the two wafers (depending on the degree of planarization), as shown in FIG. 7.

The adhesive layer 3 is removed by a debonding or photo-thermal release process (e.g., 3M WSS wafer-level packaging process), and the support substrate 4 is debonded, as shown in FIG. 8.

The PI sacrificial layer 2 is removed by an oxygen plasma process at a temperature of ≤150 °C or at room temperature, thereby forming the microbolometer thermal sensor hybridized with the readout integrated circuit, as shown in FIG. 9.

After wafer-level electrical and optoelectronic performance testing, the wafer is laser-cut into individual hybrid microbolometer thermal sensor dies with readout integrated circuits. The metal signal contacts exposed after laser cutting can use wafer fab processes to connect to the ROIC layout with embedded wiring and achieve wire-bonding-free packaging, eliminating the risk of reduced yield due to wire bonding.

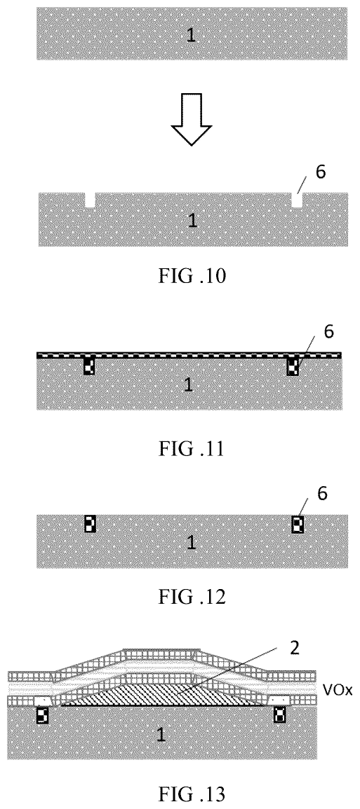

Please refer to FIGS. 10 to 18, which are process schematic diagrams of a second embodiment of the fabrication method for a microbolometer thermal sensor hybridized with a readout integrated circuit according to the present invention.

On a silicon or glass substrate 1, photolithography is performed to define hole locations matching the coordinates of the vanadium metal contact points 5 of the microbolometer thermal sensor in each pixel (as shown in FIG. 3). An ICP etching process is then used to form hole 6 with a depth greater than 50 μm, similar to Example 1, as shown in FIG. 10.

The hole 6 are filled with metal by electroplating or sputtering. In this embodiment, copper is used, but gold or other low-resistivity, high-purity metals can also be used. The total metal thickness must exceed the depth of the hole 6. In this embodiment, the total thickness exceeds 60 μm (comprising the depth of the hole 6 and other areas outside the hole), as shown in FIG. 11.

A mechanical and CMP process is performed to remove the metal layer outside the hole 6 and further reduce the thickness of the silicon or glass substrate 1, reducing the hole depth to 30 μm, as shown in FIG. 12.

The MEMS process is then used to fabricate the microbolometer floating structure sensor according to the process steps described in Example 1, as follows. On the silicon or glass substrate 1, a MEMS process is used to sequentially deposit a metal IR reflective layer (thickness 300 nm to 700 nm), coat a PI sacrificial layer 2 (thickness 3 μm to 4 μm), perform high-temperature curing (thickness reduced to 2 μm to 3 μm), and perform photolithography to define the membrane area of the microbolometer thermal sensor (designed according to pixel size). Then, PECVD and sputtering processes are used to sequentially deposit a membrane support layer (dielectric material such as SiNx or SiOx, but not limited thereto), an IR absorbing layer (metal oxide material such as VOx or TiOx, but not limited thereto), a device metal connection layer (primarily vanadium metal or other metals that form ohmic contact with the IR absorbing layer), and a top coating layer (same material as the membrane support layer). The total stress of the laminated materials is between-100 MPa and 100 MPa. Upon completion, the microbolometer thermal sensor is shown in FIG. 13.

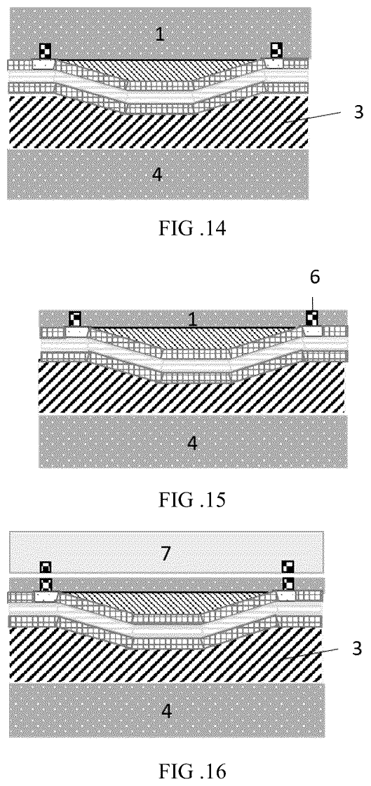

The support wafer bonding and curing process is then performed as in Example 1. An adhesive layer 3 is formed on the microbolometer thermal sensor and bonded to a support substrate 4, as shown in FIG. 14.

The underlying wafer of the microbolometer thermal sensor is then thinned to less than 50 μm, preferably less than 20 μm in this embodiment, exposing the metal regions on the hole 6 after grinding, as shown in FIG. 15, to facilitate the subsequent flip-chip metal bonding with the readout integrated circuit wafer 7.

The hybrid metal bonding process with the readout integrated circuit wafer 7 is performed as in Example 1, as shown in FIG. 16.

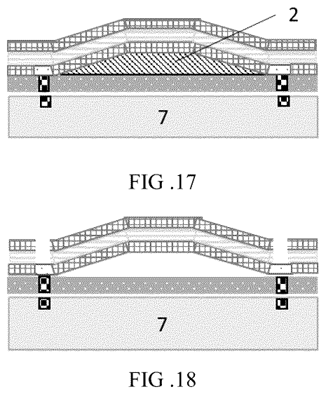

The adhesive layer 3 is removed by a debonding or photo-thermal release process, and the support substrate 4 is debonded, as shown in FIG. 17.

The PI sacrificial layer 2 is then removed by an oxygen plasma process, thereby completing the microbolometer thermal sensor wafer hybridized with the readout integrated circuit, as shown in FIG. 18.

The above describes in detail the fabrication processes for two embodiments of the microbolometer thermal sensor hybridized with the readout integrated circuit in the present invention. All of the described methods fall within the scope of protection claimed in this patent.

In summary, the two fabrication methods for the microbolometer thermal sensor hybridized with the readout integrated circuit proposed in the above embodiments address the problems encountered in the prior art. The yield sensitivity to wafer flatness variations in ROIC wafers completed at the wafer fab is not significant in this patent, and the process is expected to improve the bonding quality between the hybridized ROIC and the microbolometer thermal sensor metal contacts and the floating structure quality.

The above embodiments are merely illustrative of the features and effects of the present invention and are not intended to limit the scope of the substantive technical content of the present invention. Those skilled in the art may make modifications and changes to the above embodiments without departing from the spirit and scope of the invention. Therefore, the scope of protection of the present invention shall be defined by the following claims.

What is claimed is:

1. A fabrication method for a membrane-film microbolometer thermal sensor hybridized with a readout integrated circuit, comprising the steps of:
(A) performing a MEMS process on a semiconductor silicon substrate or a glass substrate to coat a sacrificial layer and to deposit layers by using plasma-enhanced chemical vapor deposition and sputtering to complete a microbolometer thermal sensor;
(B) flipping an entire wafer of the microbolometer thermal sensor and forming an adhesive layer, the adhesive layer being bonded and cured with a support substrate;
(C) performing a thinning and grinding process on the semiconductor silicon substrate or the glass substrate, and subsequently performing a hole patterning with yellow light lithography process at coordinates matching two metal contact points on metal pads of the microbolometer thermal sensor;
(D) after the hole patterning with yellow light lithography process, using a reactive ion etching (RIE) process to etch a hole and filling the hole with metal by sputtering or electroplating;
(E) performing a chemical mechanical polishing (CMP) process to remove the metal outside the hole and further thinning the semiconductor silicon substrate or the glass substrate;
(F) performing a flip-chip hybrid metal bonding process to bond with a readout integrated circuit wafer;
(G) removing the adhesive layer by using a de-waxing and de-bonding process or by using a photo-thermal release agent to de-bond the support substrate; and
(H) subsequently removing the sacrificial layer by using oxygen plasma to complete the membrane-film microbolometer thermal sensor wafer hybridized with the readout integrated circuit.

2. The fabrication method of claim 1, wherein the thinning and grinding process in step (C) comprises a coarse and fine grinding process, followed by chemical mechanical polishing to reduce surface roughness when the thickness of the semiconductor silicon substrate or the glass substrate is reduced to ≤30 μm.

3. The fabrication method of claim 1, wherein the metal filling thickness in step (D) exceeds the hole depth by 10 μm.

4. The fabrication method of claim 1, wherein after the chemical mechanical polishing process in step (E), the thickness of the semiconductor silicon substrate or the glass substrate is 20 μm.

5. A fabrication method for a membrane-film microbolometer thermal sensor hybridized with a readout integrated circuit, comprising the steps of:
(A) performing a hole patterning with yellow light lithography process on a semiconductor silicon substrate or a glass substrate at coordinates matching two metal contact points on metal pads through each pixel of a microbolometer thermal sensor, and using a reactive ion etching (RIE) process to etch a hole;
(B) filling the hole with metal by sputtering or electroplating;
(C) performing a chemical mechanical polishing (CMP) process to remove the metal outside the hole and further thinning the semiconductor silicon substrate or the glass substrate to reduce the hole depth to 30 μm;
(D) performing a MEMS process to coat a sacrificial layer and to deposit layers by using plasma-enhanced chemical vapor deposition and sputtering to complete the microbolometer thermal sensor;
(E) forming an adhesive layer on the microbolometer thermal sensor, and the adhesive layer being bonded and cured with a support substrate;
(F) performing a thinning and grinding process on the semiconductor silicon substrate or the glass substrate and exposing the metal on the hole after polishing;
(G) performing a flip-chip hybrid metal bonding process to bond with a readout integrated circuit wafer;
(H) removing the adhesive layer by using a de-waxing and de-bonding process or by using a photo-thermal release agent to de-bond the support substrate; and
(I) subsequently removing the sacrificial layer by using oxygen plasma to complete the membrane-film microbolometer thermal sensor wafer hybridized with the readout integrated circuit.

6. The fabrication method of claim 5, wherein the hole depth after the etching process in step (A) is greater than 50 μm.

7. The fabrication method of claim 5, wherein the metal used in step (B) is copper.

8. The fabrication method of claim 5, wherein the thickness of the semiconductor silicon substrate or the glass substrate after the thinning and grinding process in step (F) is less than 50 μm.
